(19) United States
(12) Patent Application Publication
(10) Pub. No.: US 2012/0238044 A1
(43) Pub. Date: Sep. 20, 2012

(54) METHOD FOR MANUFACTURING SEMICONDUCTOR DEVICE AND REINFORCING PLATE

(75) Inventor: Hironobu SHIBATA, Hyogo-ken (JP)

(73) Assignee: Kabushiki Kaisha Toshiba, Tokyo (JP)

(21) Appl. No.: 13/235,165

(22) Filed: Sep. 16, 2011

(30) Foreign Application Priority Data
Mar. 18, 2011 (JP) 2011-060275

(51) Int. Cl. H01L 21/66; B32B 3/10

(52) U.S. Cl. 438/17; 428/138; 438/460; 257/E21.531

(57) ABSTRACT

According to one embodiment, in a method for manufacturing a semiconductor device, a semiconductor substrate having a plurality of first pads is covered with a bonding material. The semiconductor substrate is attached to a reinforcing plate having a plurality of first through-holes corresponding respectively to the first pads. The semiconductor substrate is removed until becoming a predetermined thickness. An electrode film is formed on the semiconductor substrate. A remover of the bonding material is injected into the first through-holes so as to expose the first pads. A probe is in contact with the exposed first pads through the first through-holes so as to measure a current flowing between the probe and the electrode film. The remover is injected into the first through-holes so as to separate the semiconductor substrate from the reinforcing plate. The semiconductor substrate is diced into a plurality of chips.

### CROSS REFERENCE TO RELATED APPLICATION

This application is based upon and claims the benefit of priority from the prior Japanese Patent Application No. 2011-060275, filed on Mar. 18, 2011, the entire contents of which are incorporated herein by reference.

### FIELD

Embodiments described herein relate generally to a method for manufacturing a semiconductor device and a reinforcing plate.

### BACKGROUND

For vertical power semiconductor devices in which a current flows in a thickness direction of a semiconductor substrate, the semiconductor substrate is reduced in thickness from the original thickness during a manufacturing process in order to reduce conduction loss. In addition, to increase productivity, such vertical power semiconductor devices are manufactured by using a semiconductor substrate having a large diameter.

Moreover, after a semiconductor substrate is thinned and processed to function, defective elements need to be identified in advance by measuring element characteristics of the substrate still in the form of a wafer in a simple measurement once in order to increase productivity in an inspection prior to shipment. This reduces a burden imposed on a final measurement performed on chips into which the substrate is diced.

Power semiconductor devices are required to be guaranteed to operate in a high-temperature environment, and hence the element characteristics need to be measured in a condition similar to that for actual operation.

However, thinned semiconductor substrates with large diameter tend to curve largely. Accordingly, such semiconductor substrates have a problem of being difficult to convey by using a conveyor and likely to be damaged extremely easily.

### BRIEF DESCRIPTION OF THE DRAWINGS

FIGS. 1A and 1B are views showing a semiconductor device according to a first embodiment;

FIG. 2 is a cross-sectional view showing a main portion of the semiconductor device according to the first embodiment;

FIGS. 3A and 3B are views showing a reinforcing plate according to the first embodiment;

FIGS. 4A and 4B are cross-sectional views showing a process of manufacturing the reinforcing plate in order according to the first embodiment;

FIGS. 5A to 5C to FIGS. 8A to 8C are cross-sectional views showing a process of manufacturing the semiconductor device in order according to the first embodiment;

FIG. 9 is a cross-sectional view showing a reinforcing plate according to a second embodiment;

FIGS. 10A to 10D are cross-sectional views showing a process of manufacturing the reinforcing plate in order according to the second embodiment;

FIGS. 11A to 11C and FIGS. 12A and 12B are cross-sectional views showing main portions of a process of manufacturing a semiconductor device in order according to the second embodiment;

FIG. 13 is a cross-sectional view showing a reinforcing plate according to a third embodiment;

FIGS. 14A to 14D are cross-sectional views showing main portions of a process of manufacturing the reinforcing plate in order according to the third embodiment;

FIG. 15 is a cross-sectional view showing a main portion of a process of manufacturing a semiconductor device according to the third embodiment.

### DETAILED DESCRIPTION

According to one embodiment, in a method for manufacturing a semiconductor device, a semiconductor substrate having a first surface, a second surface opposite to the first surface, and a plurality of first pads selectively formed on the first surface side is covered with a bonding material. The semiconductor substrate is attached to a reinforcing plate having a first surface, a second surface opposite to the first surface, and a plurality of first through-holes corresponding respectively to the first pads, while the first pads and the first through-holes are aligned to correspond to each other. The semiconductor substrate being attached to the reinforcing plate is removed from the second surface side until becoming a predetermined thickness. A predetermined process is performed and an electrode film is formed on the second surface side of the semiconductor substrate. A remover of the bonding material is injected into the first through-holes so as to expose the first pads. A probe is in contact with the exposed first pads through the first through-holes so as to measure a current flowing between the probe and the electrode film. The remover of the bonding material is injected into the first through-holes so as to separate the semiconductor substrate from the reinforcing plate. The semiconductor substrate separated from the reinforcing plate is diced into a plurality of chips.

Hereinafter, embodiments will be described with reference to the drawings. In the drawings, same reference characters denote the same or similar portions.

### First Embodiment

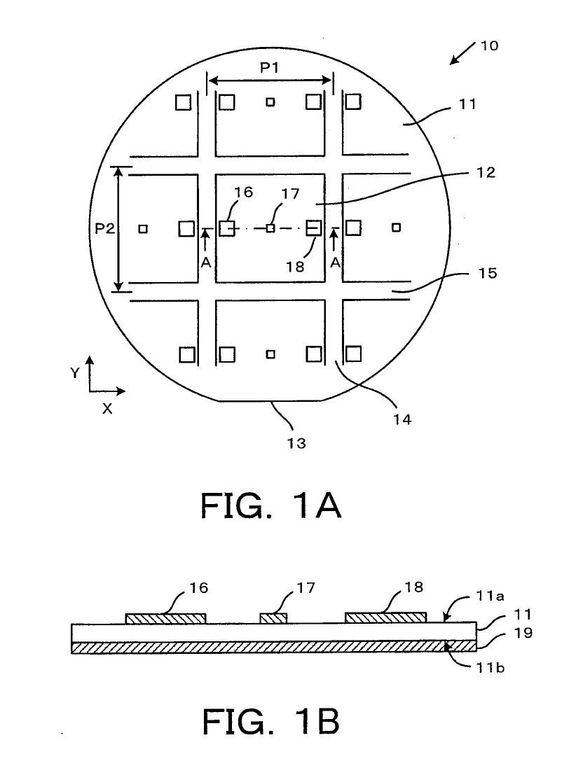

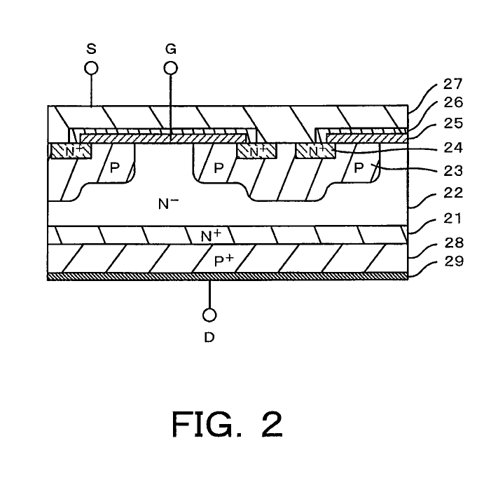

A method for manufacturing a semiconductor device of an embodiment will be described with reference to FIGS. 1A and 1B to FIGS. 8A to 8C. FIGS. 1A and 1B are views showing a semiconductor device of the embodiment. FIG. 1A is a plan view of the semiconductor device, and FIG. 1B is a cross-sectional view taken along a line A-A in FIG. 1A and seen in an arrow direction indicated in FIG. 1A. FIG. 2 is a cross-sectional view showing a main portion of the semiconductor device.

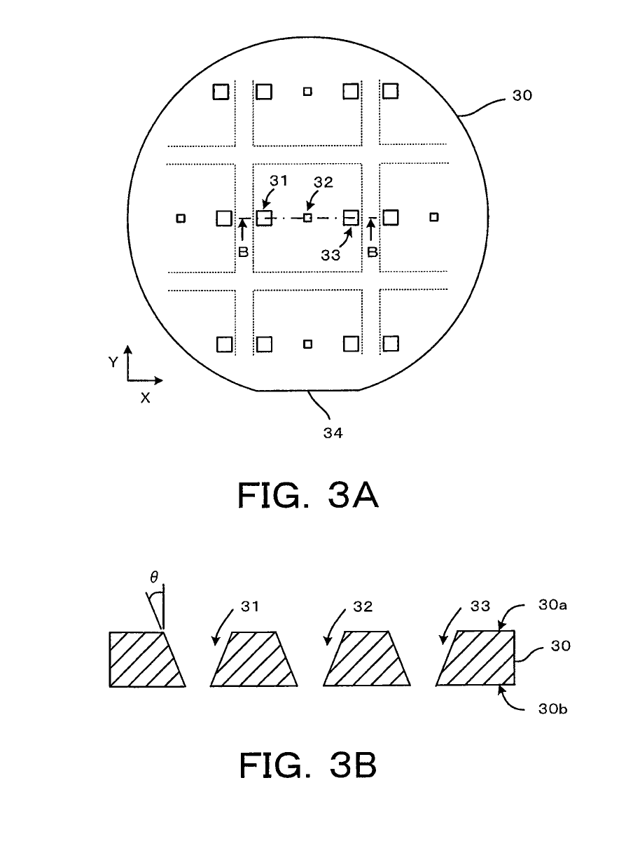

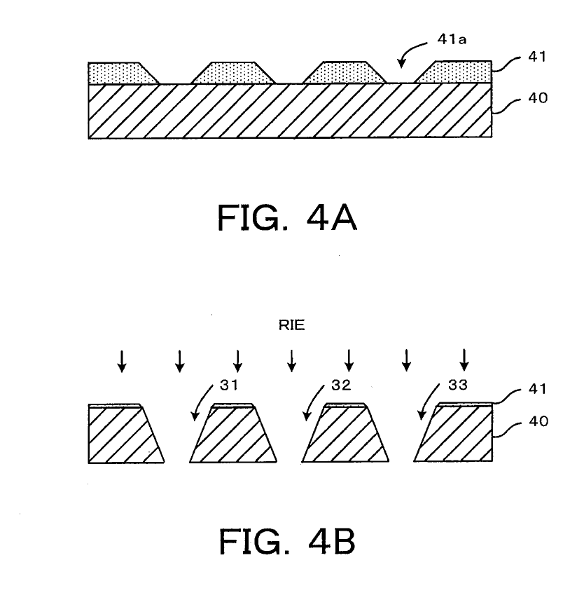

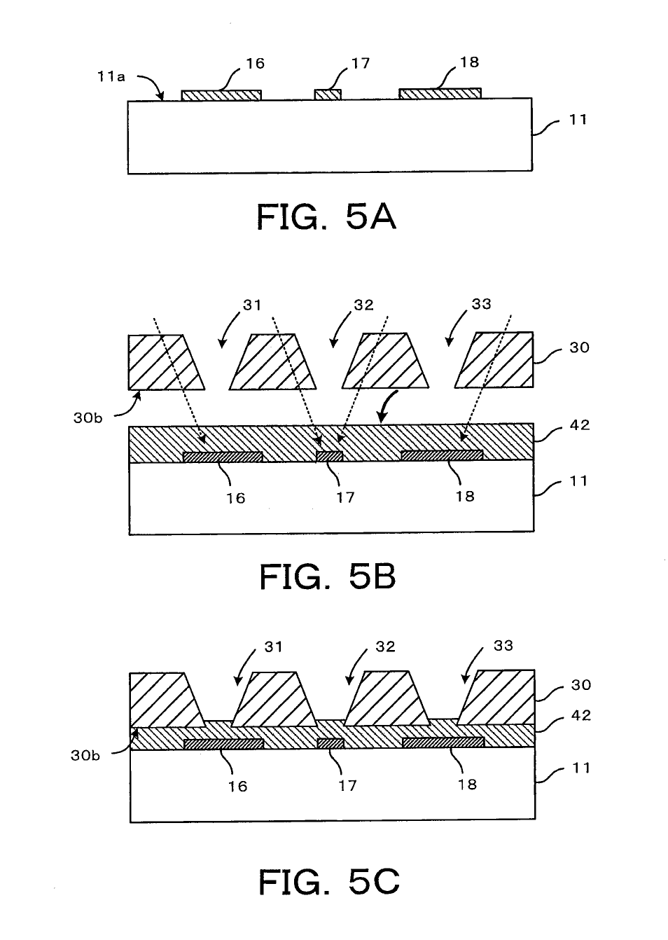

FIGS. 3A and 3B are views showing a reinforcing plate. FIG. 3A is a plan view of the reinforcing plate, and FIG. 3B is a cross-sectional view taken along a line B-B in FIG. 3A and seen in an arrow indicated in FIG. 3A. FIGS. 4A and 4B are cross-sectional views showing a process of manufacturing the reinforcing plate in order. FIGS. 5A to 5C to FIGS. 8A to 8C are cross-sectional views showing a process of manufacturing the semiconductor device in order.

As shown in FIGS. 1A and 1B, in a semiconductor device 10 of the embodiment, a semiconductor substrate is an N⁻ type silicon substrate having a diameter of 200 mm and a thickness of 50 μm, for example. The semiconductor substrate 11 includes multiple vertical semiconductor elements 12, each of which is a power semiconductor element having a size of several millimeters, for example.

The multiple semiconductor elements 12 are arranged at a pitch P1 in an X direction, which is parallel to an orientation flat 13, while being arranged at a pitch P2 in a Y direction, which is orthogonal to the X direction. Dicing lines 14, which are arranged at the pitch P1 in the X direction, are located between the semiconductor elements 12 adjacent to each other in the X direction. Similarly, dicing lines 15, which are arranged at the pitch P2 in the Y direction, are located between the semiconductor elements 12 adjacent to each other in the Y direction.

In other words, the dicing lines 14, 15 are formed in a grid on a first surface 11a of the semiconductor substrate 11. Each of the semiconductor elements 12 is formed in a rectangular area surrounded by corresponding ones of the dicing lines 14, 15.

For a measurement of element characteristics in a process of manufacturing the semiconductor device 10, first pads 16, 17, 18 to measure element characteristics are formed on the first surface 11a of the semiconductor substrate 11 for each of the semiconductor elements 12.

No pads other than the first measurement pads 16, 17, 18, such as bonding pads, for example, are illustrated in FIGS. 1A and 1B. An electrode film 19 is formed on a second surface 11b of the semiconductor substrate 11, the second surface 11b being opposite to the first surface 11a.

The semiconductor substrate 11 is ground in the process of manufacturing the semiconductor device 10, and is consequently thinned from an original thickness of 700 μm to 50 μm, for example. As will be described later, the semiconductor substrate 11 is thinned in a state of being attached to a reinforcing plate. The electrode film 19 is formed on the semiconductor substrate 11 in the state where the semiconductor substrate 11 is attached to the reinforcing plate.

The semiconductor device 10 is formed in a wafer first, and is divided into semiconductor chips each including one of the semiconductor elements 12, at the end. The semiconductor substrate 11 is placed on a dicing stage and is then cut along the dicing lines 14, 15 by a blade having a thickness of 50 μm, for example. The width of each of the dicing lines 14, 15 is twice as large as the thickness of the blade, i.e. approximately 100 μm, for example.

The above-described measurement of element characteristics is performed at a timing which is after the semiconductor substrate 11 is thinned and processed to function and is often immediately before the semiconductor substrate 11 is diced. The element characteristics of the semiconductor elements 12 need to be measured in a predetermined temperature condition so as to guarantee the semiconductor elements 12 to operate in a high-temperature environment. The semiconductor substrate 11, if thinned to a thickness of 50 μm, tends to curve largely, and is hence likely to be damaged during manufacturing operations.

The semiconductor elements 12 are IGBTs (Insulated Gate Bipolar Transistors), for example. A structure of an IGBT, although being well known, will be described in short below.

As shown in FIG. 2, in an IGBT, an N⁻ type drift layer 22 is formed on one surface of an N⁺ type buffer layer 21.

A P type base layer 23 is formed in an upper portion of the N⁻ type drift layer 22. An N⁺ type source layer (cathode) 24 (first diffusion layer) is formed in an upper portion of the P type base layer 23.

A gate electrode 25 (control electrode) is formed on the P type base layer 23 with a gate insulating film (not shown) interposed between the gate electrode 25 and the P type base layer 23, so as to be positioned above a portion of the P type base layer 23, the portion being sandwiched between the N⁻ type drift layer 22 and the N⁺ type source layer 24.

An insulating film 26 is formed so as to cover the gate electrode 25. A source metal 27 electrically connected to the P type base layer 23 is formed. An unillustrated gate metal electrically connected to the gate electrode 25 is formed.

A P⁺ type drain layer (anode) 28 (second diffusion layer) is formed on the other surface of the N⁺ type buffer layer 21. A drain metal 29 is formed on the P⁺ type drain layer 28.

The N⁻ type drift layer 22, the P type base layer 23, the N⁺ type source layer 24 and the gate electrode 25 form an N-channel MOS transistor structure.

The N⁺ type drain layer 28, the N⁺ type buffer layer 21 and the P type base layer 23 form a PNP bipolar transistor. Low saturation voltage characteristics of the IGBT are obtained through conductivity modulation of the PNP bipolar transistor.

The first pad 16 is electrically connected to the source metal 27, for example. The first pad 17 is electrically connected to the gate metal, for example. The first pad 18 is connected to a sensing element to monitor the temperature of the element or a current flowing through the element, for example. The electrode film 19 is the drain metal 29.

As shown in FIGS. 3A and 3B, a reinforcing plate 30 is a translucent base plate through which the semiconductor substrate 11 can be seen, a glass plate, for example. The reinforcing plate 30 has approximately the same size as the original size of the semiconductor substrate 11, i.e. a diameter of 200 mm and a thickness of 700 μm.

First through-holes 31, 32, 33 corresponding respectively to the first pads 16, 17, 18 shown in FIGS. 1A and 1B are formed in the reinforcing plate 30. The first through-holes 31, 32, 33 are holes to allow probes to come in contact with the first pads 16, 17, 18 in measuring the characteristics of the semiconductor element 12.

In consideration of this function, it is preferable to form each of the first through-holes 31, 32, 33 in a shape broadened toward a first surface 30a from a second surface 30b (a forward tapered shape when seen from the first surface 30a) with inclining side surfaces so that tips of the probes would easily be inserted into the first through-holes 31, 32, 33, respectively.

An appropriate inclination angle θ for each side surface is approximately 10° to 20°, for example, from a viewpoint that an opening of each of the first through-holes 31, 32, 33 in the first surface 30a would not interfere with a pad adjacent to the one corresponding to the first through-hole.

Further, it is preferable that an orientation flat 34, which is approximately the same as the orientation flat 13 of the semiconductor substrate 11, be formed for the reinforcing plate 30, so as to facilitate alignment of the first pads 16, 17, 18 and the first through-holes 31, 32, 33 with each other.

The reinforcing plate 30 having the first through-holes 31, 32, 33 are formed as follows, for example. As shown in FIG. 4A, a resist film 41 having openings 41a each being in a forward tapered shape is formed on a glass plate 40 by photolithography by controlling a focus and exposure.

Subsequently, as shown in FIG. 4B, the glass plate 40 is subjected to anisotropic etching by RIE (Reactive Ion Etching) using a fluorine-based gas, for example, by using the resist film 41 as a mask. In this step, the resist film 41 is also etched in accordance with a selection ratio of the glass plate 40 and the resist film 41, and thereby the diameter of each opening in the resist film 41 increases gradually. As a result, the first through-holes 31, 32, 33 each being in a forward tapered shape are formed.

Thereafter, the remaining resist film 41 is removed by using an asher, for example, and consequently the reinforcing plate 30 having first through-holes 31, 32, 33 is obtained.

When the thickness of the reinforcing plate 30 is 700 μm, and the size of the first through-holes 31, 32, 33 is 100 μm, for example, the aspect of the first through-holes 31, 32, 33 is 7. The first through-holes 31, 32, 33 can be formed by using a RIE apparatus for deep silicon etching, for example. Further, the resist film 41 having openings each being in a forward tapered shape can be formed by imprinting, alternatively.

Next, a method for manufacturing a semiconductor device 10 of the embodiment will be described. The method for manufacturing the semiconductor device 10 of the embodiment is designed to be able to measure element characteristics of semiconductor elements 12 while the semiconductor device 10 is formed in a wafer, in a condition similar to that when the semiconductor device 10 is in operation.

As shown in FIG. 5A, an IGBT (not shown), except for a P⁺ type drain layer 28 and a drain metal 29 to form a collector, is formed as the semiconductor element 12, on a first surface 11a of the semiconductor substrate 11 having an original thickness of 700 μm.

Specifically, an N⁻ type drift layer 22 is formed on the N⁺ type semiconductor substrate 11 to serve as an N⁺ type buffer layer 21 by epitaxy, for example. A P type base layer 23 is formed in an upper portion of the N⁻ type drift layer 22 by ion implantation, for example. An N⁺ type source layer 24 is formed in an upper portion of the P⁺ type base layer 23 by ion implantation, for example.

The gate insulating film is formed on a portion of the P type base layer 23, the portion being sandwiched between the N⁻ type drift layer 22 and the N⁺ type source layer 24, by thermal oxidation, for example. A polysilicon layer is formed as a gate electrode 25 on a gate insulating film by CVD (Chemical Vapor Deposition), for example. A silicon oxide film is formed as an insulating film 26 to cover the gate electrode 25, by CVD, for example.

An aluminum (Al) film is formed as a source metal 27 on the insulating film 26, portions of the P type base layer 23 and the N⁺ type source layer 24, the portions being exposed from the insulating film 26, by sputtering, for example.

Similarly, the gate metal electrically connected to the gate electrode 25 is formed. First measurement pads 16, 17, 18 to measure the element characteristics of the semiconductor element 12 are selectively formed on a first surface 11a of the semiconductor substrate 11.

As shown in FIG. 5B, a bonding material 42 is applied to the semiconductor substrate 11 so as to cover the first pads 16, 17, 18. The bonding material 42 is a bonding material having a heat resistance (up to 200° C., for example), and a material obtained by removing photosensitive components from a resist material is used for the bonding material 42, for example. A resist material is easy to apply and separate.

The first pads 16, 17, 18 of the semiconductor substrate 11 are aligned with first through-holes 31, 32, 33, respectively, and a reinforcing plate 30 is placed upon the semiconductor substrate 11. In this step, the alignment is easily performed since the positions of the first pads 16, 17, 18 can be visually recognized through the reinforcing plate 30 made of a glass plate.

As shown in FIG. 5C, the bonding material 42 is cured while the reinforcing plate 30 is pressed against the semiconductor substrate 11 with the bonding material 42 sandwiched between the reinforcing plate 30 and the semiconductor substrate 11, to thereby bond (join) the semiconductor substrate 11 and the reinforcing plate 30 with each other. In this state, the bonding material 42 swells out from a second surface 30b into the first through-holes 31, 32, 33, and the first pads 16, 17, 18 are covered with the bonding material 42.

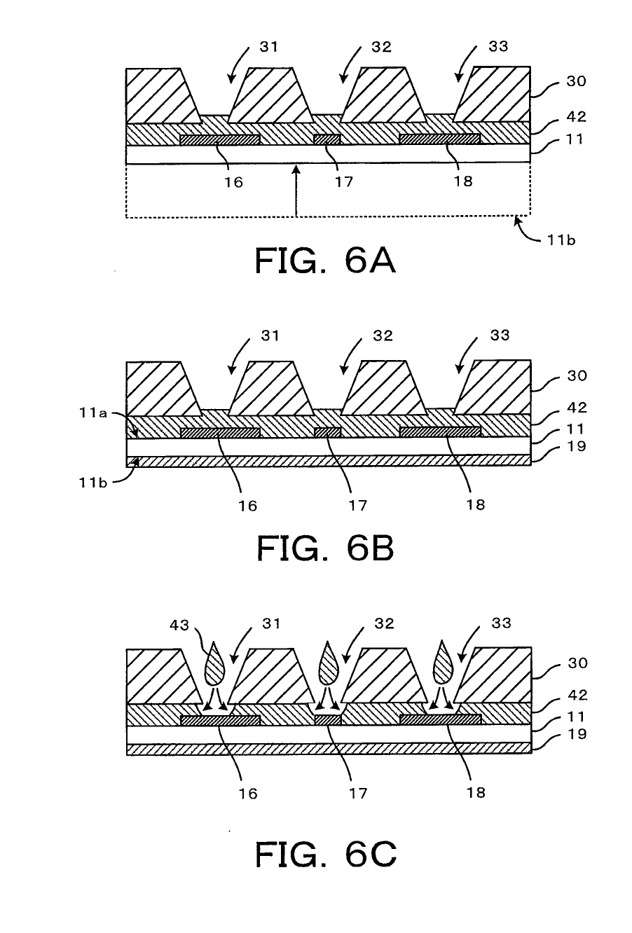

As shown in FIG. 6A, the semiconductor substrate 11 is thinned from 700 μm to 50 μm. Specifically, the reinforcing plate 30 is fixed to a stage of a grinder, for example, and the semiconductor substrate 11 is ground from the second surface 11b side.

When the semiconductor substrate 11 is ground to a predetermined thickness, wet etching, for example, is performed to remove a fractured layer generated on the second surface lib side of the semiconductor substrate 11. Further, the second surface 11b side of the semiconductor substrate 11 is polished to improve surface smoothness of the semiconductor substrate 11.

In this way, the semiconductor substrate 11 is reinforced by the reinforcing plate 30, and maintains approximately the same thickness as the original one. Accordingly, the semiconductor substrate 11 thus formed can be conveyed in a usual manner.

As shown in FIG. 6B, the P⁺ type drain layer 28 (not shown) is formed on the second surface 11b of the semiconductor substrate 11, and then the drain metal 29 (electrode film 19) is formed on the P⁺ type drain layer 28.

Specifically, implantation of ions of boron (B), for example, as P type impurities into the second surface 11b side of the semiconductor substrate 11, is performed, and activation of B is performed. This activation is performed by RTA (Rapid Thermal Annealing) using microwave irradiation, for example. This is to prevent the temperature of the first surface 11a side of the semiconductor substrate 11 from exceeding the heat-resistant temperature of the bonding material 42.

An Al film is formed on the P⁺ type drain layer 28 by sputtering, for example. Through the above-described steps, an IGBT which is the semiconductor element 12 can be obtained.

As shown in FIG. 6C, the bonding material 42 which is at and around bottom portions of the first through-holes 31, 32, 33 is removed by injecting, into the first through-holes 31, 32, 33, a remover 43 of the bonding material 42 such as a thinner-based organic solvent, for example.

Thereby, the first pads 16, 17, 18 are exposed from the bottom portions of the first through-holes 31, 32, 33, respectively. This allows the first pads 16, 17, 18 to come in contact with the probes.

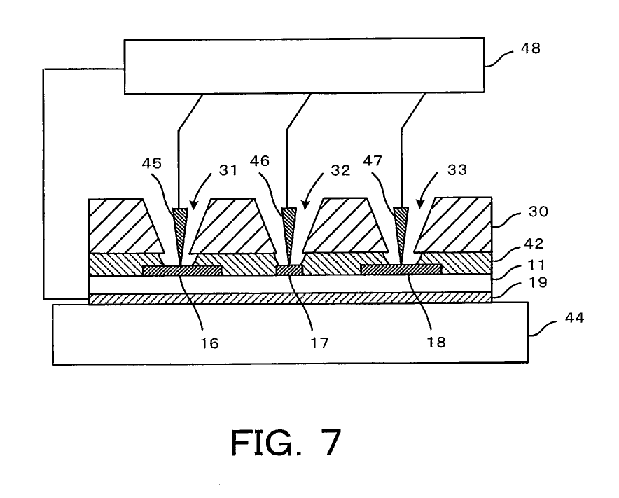

As shown in FIG. 7, the characteristics of the semiconductor element 12 are measured in the state where the reinforcing plate 30 is attached to the semiconductor substrate 11. Specifically, the semiconductor substrate 11 is fixed onto a stage 44. The stage 44 includes a built-in heater (not shown). The semiconductor substrate 11 is heated up to a predetermined guaranteed temperature or the like of the semiconductor element 12, by the heater.

Probes 45, 46, 47 are inserted into the through-holes 31, 32, 33, respectively, and thereby made into contact with the pads 16, 17, 18, respectively. Since the first through-holes 31, 32, 33 are each in a forward tapered shape, insertion of the probes 45, 46, 47 is easy.

The characteristics of the semiconductor elements 12 are measured by using a tester 48. For example, a current flowing between the probe 45 and the electrode film 19 is measured by applying a gate voltage to the first pad 17 through the probe 46.

Defective elements may be marked by checking the quality of the semiconductor elements 12 on the basis of the measurement results. Alternatively, the semiconductor elements 12 may be ranked in accordance with the measurement results.

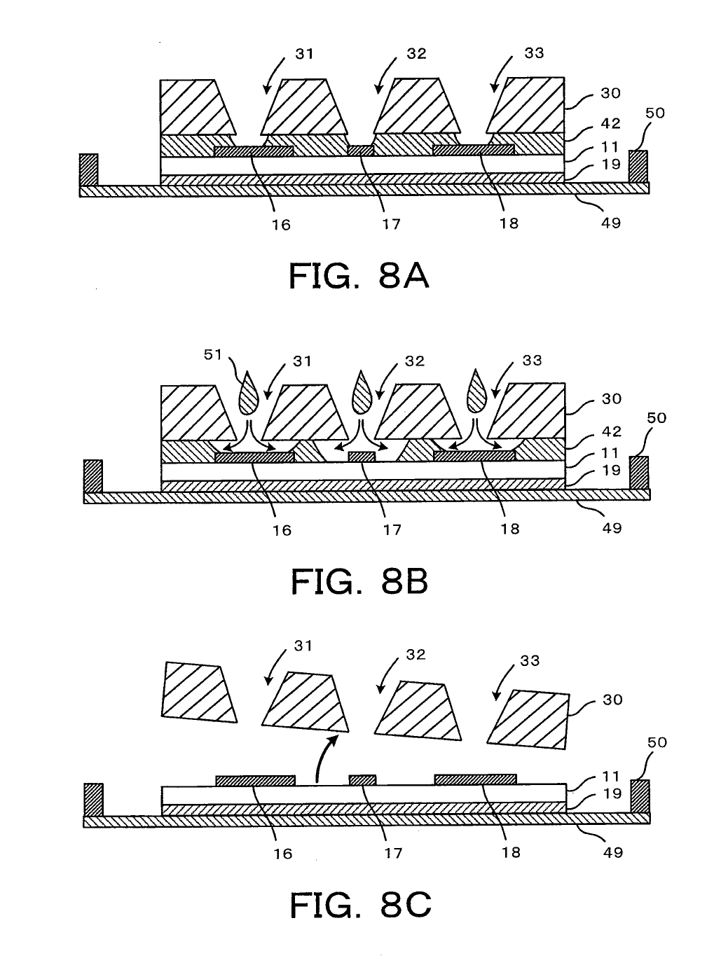

As shown in FIG. 8A, the semiconductor substrate 11 to which the reinforcing plate 30 is attached, is detached from the stage 44, and is then attached to a dicing sheet 49. The dicing sheet 49 is isotropically stretched by a dicing ring 50.

As shown in FIG. 8B, a remover 51 of the bonding material 42 is injected into the first through-holes 31, 32, 33. The remover 51 comes into spaces between the reinforcing plate 30 and the first pads 16, 17, 18 through the first through-holes 31, 32, 33, and the bonding material 42 is thereby dissolved in lateral directions, thus causing undercut to progress.

As shown in FIG. 8C, when the bonding material 42 is removed largely through the undercut, the semiconductor substrate 11 and the reinforcing plate 30 come to be separated naturally. The reinforcing plate 30 separated from the semiconductor substrate 11 is washed and then stored. This enables the reinforcing plate 30 to be used repeatedly as many times as desired.

The dicing ring 50 is fixed to a dicing stage, and the semiconductor substrate 11 is diced along the dicing lines 14, 15. In this way, the semiconductor device 10 is divided into semiconductor chips including the semiconductor elements 12, respectively.

As described above, in the embodiment, the reinforcing plate 30 including the first through-holes 31, 32, 33 corresponding respectively to the first pads 16, 17, 18 is attached to the semiconductor substrate 11 on the occasion of thinning the semiconductor substrate 11.

Consequently, the semiconductor substrate 11 can be conveyed without being damaged from the subsequent step to the step of measuring the characteristics of the semiconductor elements 12. Hence, the embodiment can provide a method for manufacturing a semiconductor device and a reinforcing plate with which a semiconductor substrate can be reinforced in the step of thinning the semiconductor substrate and the steps subsequent to the thinning step and element characteristics can be measured while the semiconductor substrate is being reinforced.

Here, descriptions have been given to a case in which the reinforcing plate 30 is made of glass. However, the reinforcing plate 30 may be made of any material as long as the material has transparency to visible light and heat resistance, and may therefore be made of resin.

Alternatively, silicon which is transmissive to infrared light can also be used. The first pads 16, 17, 18 and the first through-holes 31, 32, 33 can be aligned with each other by using an infrared light source and an infrared camera.

However, since silicon is not an insulating material, it is preferable to use silicon with high resistivity or to form a thermal oxidation film on a surface of a silicon reinforcing plate.

Although, descriptions have been given of a case in which the semiconductor elements 12 are IGBTs, the embodiment can be applied similarly even to a case the semiconductor elements 12 are a different type of vertical semiconductor elements, such as trench-gate MOS transistors or diodes, for example. There is no problem in particular even if the embodiment is applied to horizontal semiconductor elements.

### Second Embodiment

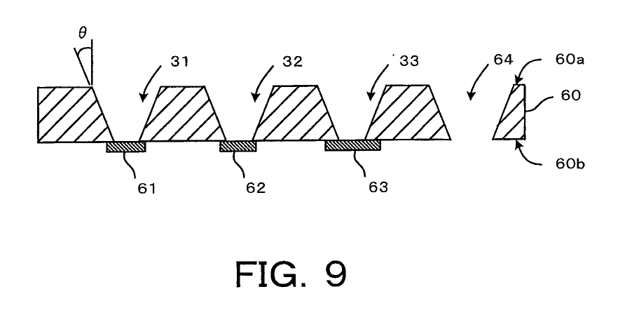

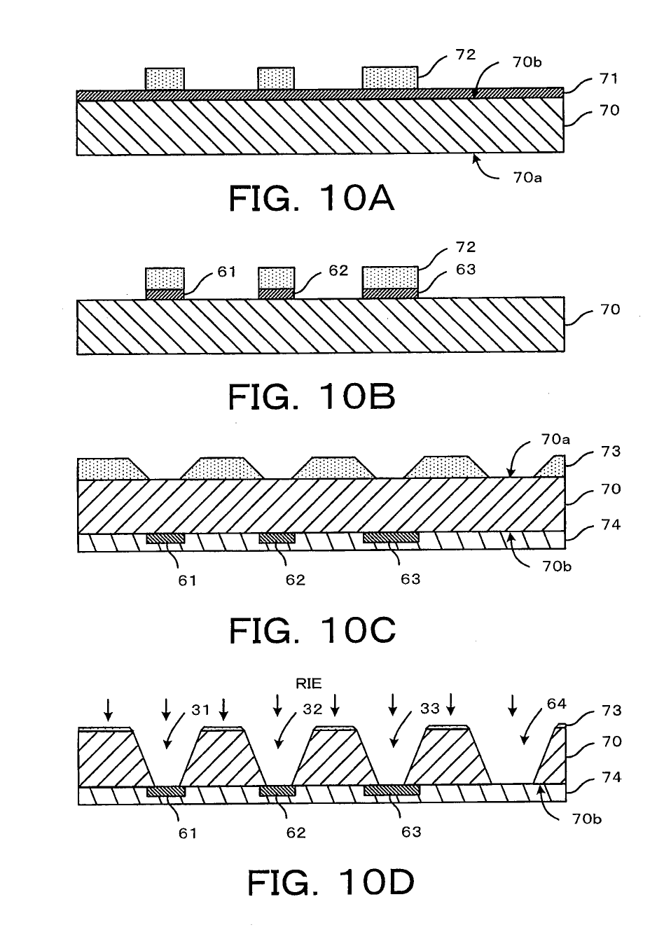

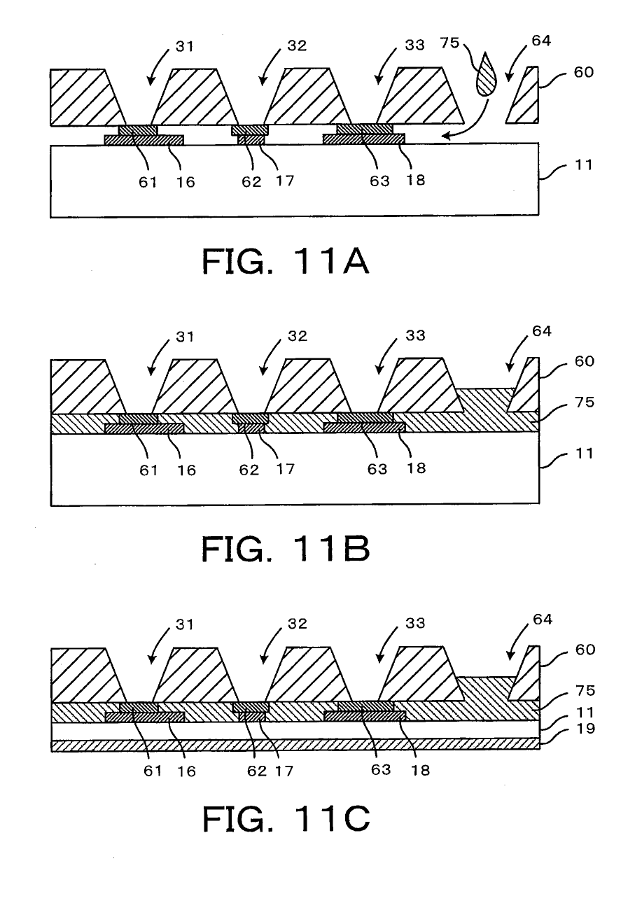

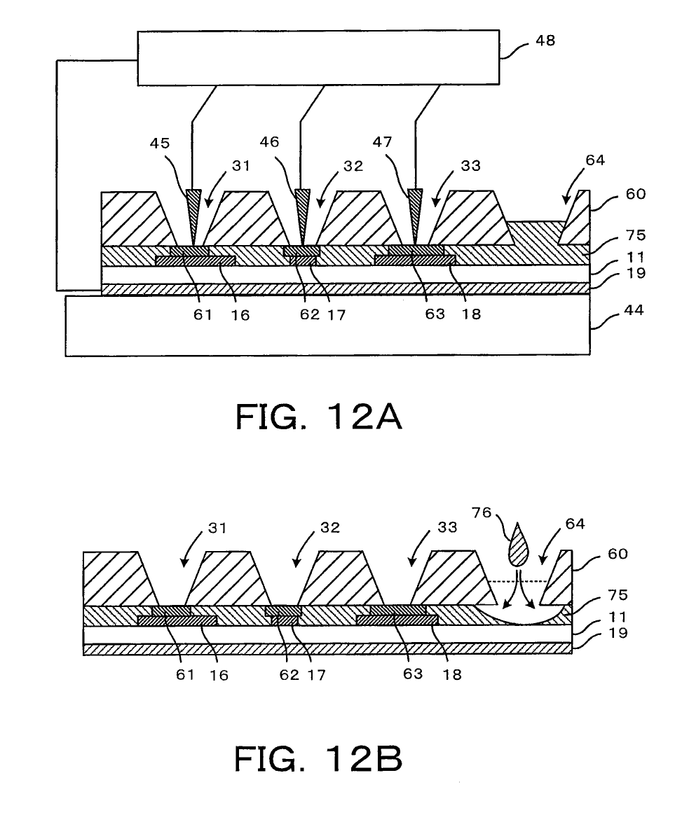

A method for manufacturing a semiconductor device of an embodiment will be described with reference to FIG. 9 to FIGS. 12A and 12B. FIG. 9 is a cross-sectional view showing a reinforcing plate of the embodiment, FIGS. 10A to 10D are cross-sectional views showing a process of manufacturing the reinforcing plate in order, and FIGS. 11A to 11C and FIGS. 12A and 12B are cross-sectional views showing main portions of a process of manufacturing a semiconductor device in order.

In the embodiment, the same components as those in the first embodiment described above are denoted by the same reference numerals, and descriptions are given to a different configuration while being omitted to the same configuration. The embodiment is different from the first embodiment in that openings of through-holes in the reinforcing plate are sealed with pads.

Specifically, in the case of a reinforcing plate 60 used in the method for manufacturing a semiconductor device of the embodiment, openings, on a second surface 60b side, of first through-holes 31, 32, 33 are sealed with second pads 61, 62, 63. Moreover, a second through-hole 64, which does not correspond to any of first pads 16, 17, 18, is formed.

The second pads 61, 62, 63 are made of a gold-plated film having a thickness of 10 to 30 μm, for example. The second through-hole 64 is in a forward tapered shape similar to those of the first through-holes 31, 32, 33.

The second pads 61, 62, 63 are provided so as to come in contact with the first pads 16, 17, 18, respectively, in order to prevent the first pads 16, 17, 18 from being covered with a bonding material in attaching a semiconductor substrate 11 and the reinforcing plate 60 with the bonding material interposed between the semiconductor substrate 11 and the reinforcing plate 60.

The bonding material is injected into the second through-hole 64. The second though-hole 64 is provided as an injection port to cause the bonding material to come into a space between the semiconductor substrate 11 and the reinforcing plate 60.

The reinforcing plate 60 is formed as follows, for example. As shown in FIG. 10A, a gold-plated film 71 having a thickness of 10 to 30 μm is formed on a second surface 70b of a glass plate 70 by electroless plating, for example. A resist film 72 is formed on the gold-plated film 71, as a mask material corresponding to the openings, on the second surface 60b side, of the first through-holes 31, 32, 33 shown in FIG. 9.

As shown in FIG. 10B, wet etching using an aqua-regia-based or iodine-based etchant for gold, for example, is performed on the gold-plated film 71 by using the resist film 72 as a mask. Thereby, the second pads 61, 62, 63 to seal the openings, on the second surface 60b side, of the first through-holes 31, 32, 33 shown in FIG. 9 are formed.

As shown in FIG. 10C, the resist film 72 is removed, and thereafter a protection tape 74 is attached to the second surface 70b of the glass plate 70, to protect the second pads 61, 62, 63. The glass plate 70 is turned over, and a resist film 73 is formed on a first surface 70a of the glass plate 70 similarly to FIG. 4A, so as to have openings each being in a forward tapered shape and corresponding to the first through-holes 31, 32, 33 and the second through-hole 64, respectively.

As shown in FIG. 10D, similarly to FIG. 4B, anisotropic etching based on RIE is performed on the glass plate 70 by using the resist film 73 as a mask, to thereby form the first through-holes 31, 32, 33 and the second through-hole 64. In this event, the gold-plated film 71 is not etched by RIE.

Finally, the resist film 73 and the protection tape 74 are removed, thereby obtaining the reinforcing plate 60 including the second through-hole 64 and the second pads 61, 62, 63 to seal the openings, on the second surface 60b side, of the first through-holes 31, 32, 33 shown in FIG. 9.

Next, the method for manufacturing a semiconductor device of the embodiment will be described. As shown in FIG. 11A, first pads 16, 17, 18 of a semiconductor substrate 11 and second pads 61, 62, 63 of a reinforcing plate 60 are made into contact with each other while being aligned to correspond to each other. By maintaining this state, a bonding material 75 is injected into a second through-hole 64. The injected bonding material 75 comes into the space between the semiconductor substrate 11 and the reinforcing plate 60.

As shown in FIG. 11B, the boding material 75 is cured, and the semiconductor substrate 11 and the reinforcing plate 60 are attached to each other. In this event, since the openings, on a second surface 60b side, of first through-holes 31, 32, 33 are sealed, Upper surfaces of the second pads 61, 62, 63 are exposed without being covered with the bonding material 75. The bonding material 75 swells out from a bottom portion of the second through-hole 64 into the second through-hole 64.

As shown in FIG. 11C, similarly to FIGS. 6A and 6B, after the semiconductor substrate 11 is thinned, a P⁺ drain layer 28 and a drain metal 29 (electrode film 19) are formed.

As shown in FIG. 12A, element characteristics of semiconductor elements 12 are measured while probes 45, 46, 47 are made into contact with the second pads 61, 62, 63, respectively, similarly to FIG. 7.

As shown in FIG. 12B, similarly to FIG. 8A, after the semiconductor substrate 11 to which the reinforcing plate 60 is attached is attached to a dicing sheet 49, a remover 76 of the bonding material 75 is injected into the second through-hole 64. The bonding material 75 sandwiched between the reinforcing plate 60 and the semiconductor substrate 11 is dissolved in lateral directions through the second through-hole 64, thus causing undercut to progress.

When the bonding material 75 is removed largely through the undercut, the semiconductor substrate 11 and the reinforcing plate 60 come to be separated naturally. The reinforcing plate 60 separated from the semiconductor substrate 11 is washed and then stored. Naturally, the washing and the storing need to be carried out without damaging the second pads 61, 62, 63. This enables the reinforcing plate 30 to be used repeatedly as many times as desired.

As described above, in the embodiment, the reinforcing plate 60 including the second through-hole 64 and the second pads 61, 62, 63 to seal the openings, on the second surface 60b side, of the first through-holes 31, 32, 33 is attached to the semiconductor substrate 11.

As a result, the embodiment has an advantage that the upper surfaces of the second pads 61, 62, 63, coming into contact with the probes 45, 46, 47, can be prevented from being covered with the bonding material 75. Accordingly, the unnecessary step of removing the bonding material 42 covering the first pads 31, 32, 33 shown in FIG. 6C can be omitted.

### Third Embodiment

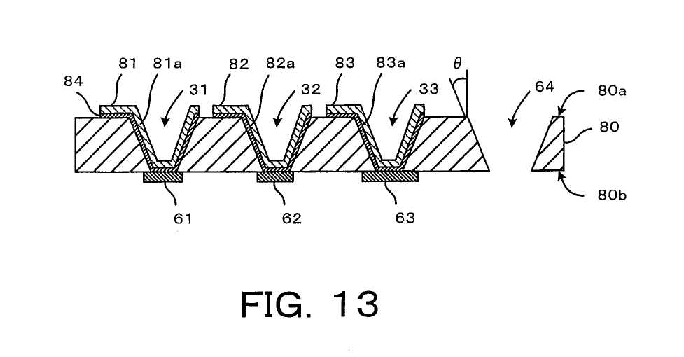

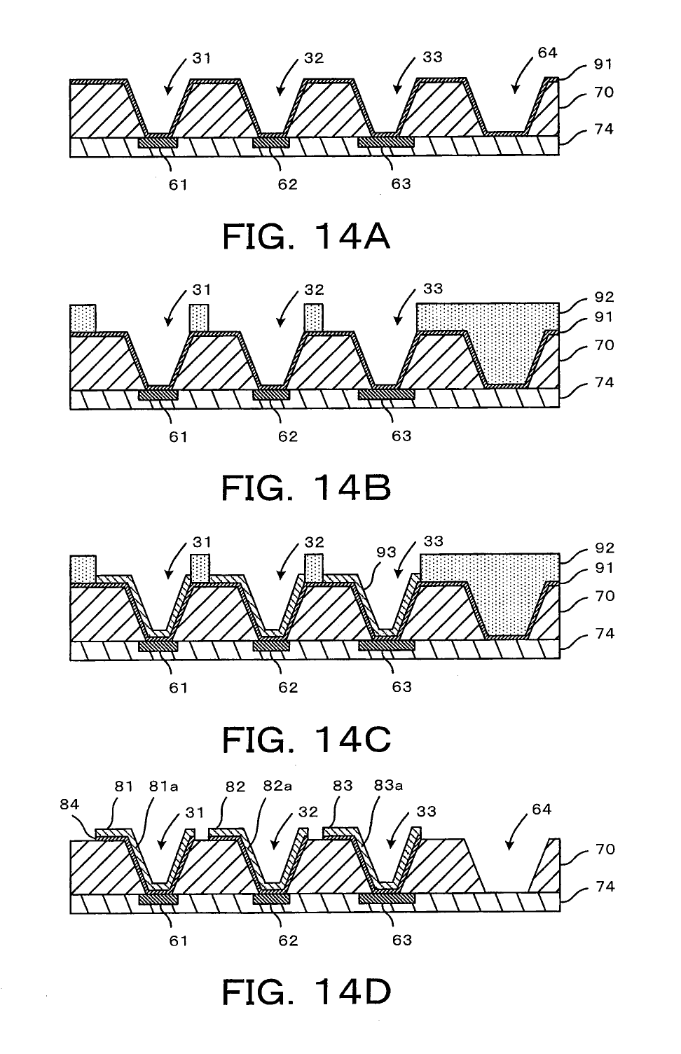

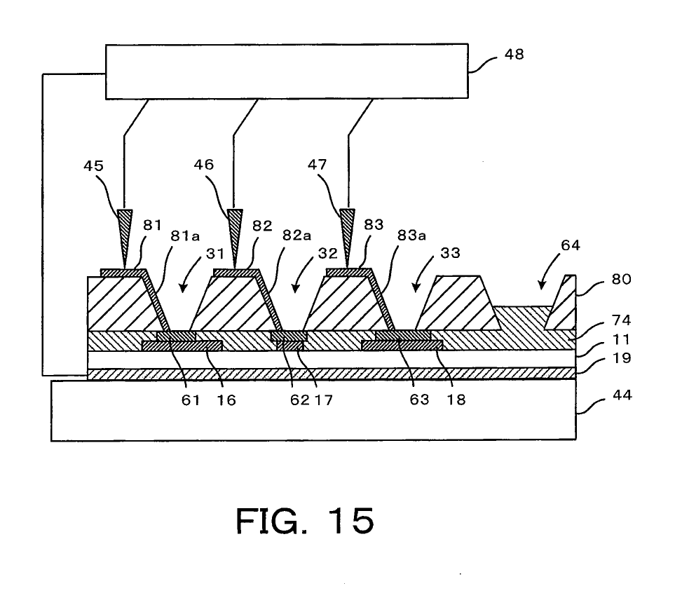

A method for manufacturing a semiconductor device of an embodiment will be described with reference to FIG. 13 to FIG. 15. FIG. 13 is a cross-sectional view showing a reinforcing plate of the embodiment, FIGS. 14A to 14D are cross-sectional views showing main portions of a process of manufacturing the reinforcing plate in order, and FIG. 15 is a cross-sectional view showing a main portion of a process of manufacturing a semiconductor device.

In the embodiment, the same components as those in the first embodiment described above are denoted by the same reference numerals, and descriptions are given to a different configuration while being omitted to the same configuration. The embodiment is different from the second embodiment in that second pads to seal openings of through-holes are raised onto the reinforcing plate.

Specifically, as shown in FIG. 13, in a reinforcing plate 80 used in the method for manufacturing a semiconductor device of the embodiment, third pads 81, 82, 83 are formed on a first surface 80a of the reinforcing plate 80. The third pads 81, 82, 83 are electrically connected to second pads 61, 62, 63, respectively, via wirings 81a, 82a, 83a formed along inclined side surfaces of first through-holes 31, 32, 33, respectively.

The third pads 81, 82, 83 are formed on the first surface 80a of the reinforcing plate 80 with a seed film 84 interposed between the third pads 81, 82, 83 and the first surface 80a. The wirings 81a, 82a, 83a are formed on entire inner surfaces (side surfaces and bottom surfaces) of the first through-holes 31, 32, 33 with the seed film 84 interposed between the wirings 81a, 82a, 83a and the inner surfaces. The seed film 84 is provided to facilitate formation of the third pads 81, 82, 83 by electrolytic plating.

Probes 45, 46, 47 come into contact with the third pads 81, 82, 83, respectively. The third pads 81, 82, 83 are provided to obtain electric connection of the probes 45, 46, 47 and a semiconductor element 12 without passing through the first through-holes 31, 32, 33.

The reinforcing plate 80 is formed as follows, for example. After the step shown in FIG. 10D, a TiN film 91, for example, to serve as the seed film 84 is formed on a first surface 70a of a glass plate 70 by sputtering, as shown in FIG. 14A.

The TiN film 91 is formed conformally on the first surface 70a, side surfaces of the first through holes 31, 32, 33 and a second through-hole 64, the second pads 61, 62, 63 and exposed portions of a protection tape 74.

As shown in FIG. 14B, a resist film 92 to fill in the second through-hole 64 is formed by photolithography by exposing the inner surfaces of the first through-holes 31, 32, 33 and portions of the first surface 70a, the portions each continuing to one side-wall of a corresponding one of the first through-holes 31, 32, 33.

As shown in FIG. 14C, a gold-plated film 93 is formed on the inner surfaces of the first through-holes 31, 32, 33 and the portions of the first surface 70a each continuing to the one side surface of the corresponding one of the first through-holes 31, 32, 33, by electrolytic plating using the resist film 92 as a mask.

As shown in FIG. 14D, after the resist film 92 is removed, portions of the TiN film 91 which are thus exposed are removed by wet etching, for example, using the gold-plated film 93 as a mask. In this way, the third pads 81, 82, 83 and the wirings 81a, 82a, 83a are formed. The protection tape 74 is removed, thereby obtaining the reinforcing plate 80 shown in FIG. 13.

Next, the method for manufacturing a semiconductor device of the embodiment will be described. The method for manufacturing a semiconductor device of the embodiment is basically similar to the method shown in FIGS. 11A to 11C and FIGS. 12A and 12B. Specifically, first pads 16, 17, 18 of a semiconductor substrate 11 and second pads 61, 62, 63 of a reinforcing plate 80 are made into contact with each other while being aligned to correspond to each other. A bonding material 75 is injected into a second through-hole 64 and is then cured, thereby attaching a semiconductor substrate 11 and the reinforcing plate 80 to each other.

However, measurement of characteristics of semiconductor elements 12 is different. As shown in FIG. 15, probes 45, 46, 47 are made into contact with third pads 81, 82, 83, respectively, instead of the second pads 61, 62, 63. This can avoid the need to insert the probes 45, 46, 47 into the first through-holes 31, 32, 33. Hence, electric connection of the probes 45, 46, 47 and the semiconductor element 12 can be obtained without passing through first through-holes 31, 32, 33.

As described above, in the embodiment, the reinforcing plate 80 including the third pads 81, 82, 83 raised onto the first surface 80a is attached to the semiconductor substrate 11.

As a result, the embodiment has an advantage that the electrical connection of the probes 45, 46, 47 and the semiconductor element 12 can easily be obtained without inserting the probes 45, 46, 47 into the first through-holes 31, 32, 33.

Moreover, the embodiment has an advantage that, since the probes 45, 46, 47 do not come into contact with the second pads 61, 62, 63, wear of the second pads 61, 62, 63 is prevented. This improves durability of the reinforcing plate 80, and enables the reinforcing plate 80 to be used repeatedly for a long time.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising:
covering with a bonding material a semiconductor substrate having a first surface, a second surface opposite to the first surface, and a plurality of first pads selectively formed on the first surface side;
attaching a reinforcing plate having a first surface, a second surface opposite to the first surface, and a plurality of first through-holes corresponding respectively to the first pads, to the semiconductor substrate while the first pads and the first through-holes being aligned to correspond to each other;
removing the semiconductor substrate being attached to the reinforcing plate from the second surface side until becoming a predetermined thickness;
performing a predetermined process and forming an electrode film, on the second surface side, of the semiconductor substrate;
injecting a remover of the bonding material into the first through-holes so as to expose the first pads;
contacting a probe and the exposed first pads through the first through-holes so as to measure a current flowing between the probe and the electrode film;
injecting the remover of the bonding material into the first through-holes so as to separate the semiconductor substrate from the reinforcing plate; and
dicing the semiconductor substrate separated from the reinforcing plate into a plurality of chips.

2. The method for manufacturing the semiconductor device according to claim 1, wherein the reinforcing plate further includes a plurality of second pads to seal the openings, on the second surface side, of the first through-holes and a second through-hole not corresponding to any of the first pads,
wherein the bonding material is injected into the second through-hole so as to attach the semiconductor substrate to the reinforcing plate while the first pads and the second pads being aligned to correspond to each other,
wherein the probe is in contact with the second pads so as to measure the current which flows between the probe and the electrode film, and
wherein the remover of the bonding material is injected into the second through-hole so as to separate the semiconductor substrate from the reinforcing plate.

3. The method for manufacturing the semiconductor device according to claim 2, wherein the reinforcing plate further includes a plurality of third pads formed on the first surface of the reinforcing plate and a plurality of wirings formed respectively along the inner surfaces of the first through-holes so as to electrically connect the second pad to the third pad, and
wherein the probe is in contact with the third pads so as to measure the current which flows between the probe and the electrode film.

4. The method for manufacturing the semiconductor device according to claim 1, wherein the semiconductor substrate is heated up to a predetermined temperature so as to measure the electric current.

5. The method for manufacturing the semiconductor device according to claim 1, wherein the reinforcing plate is washed to be used repeatedly.

6. The method for manufacturing the semiconductor device according to claim 1, wherein the bonding material is a material obtained by removing photosensitive components from a resist material.

7. The method for manufacturing the semiconductor device according to claim 1, wherein the remover is a thinner-based organic solvent.

8. The method for manufacturing the semiconductor device according to claim 2, wherein the bonding material injected into the second through-hole comes into the space between the semiconductor substrate and the reinforcing plate so that the semiconductor substrate and the reinforcing plate are attached to each other.

9. The method for manufacturing the semiconductor device according to claim 2, wherein the bonding material sandwiched between the semiconductor substrate and the reinforcing plate is dissolved in lateral directions so that the semiconductor substrate and the reinforcing plate are separated.

10. The method for manufacturing the semiconductor device according to claim 1, wherein a semiconductor element having a first diffusion layer on the first surface, a control electrode on the first surface, and the second diffusion layer on the second surface is formed on the semiconductor substrate, and
Wherein the first diffusion layer and the control electrode are electrically connected to the first pads, the second, diffusion layer is electrically connected to the electrode film.

11. A reinforcing plate to reinforce a semiconductor substrate having a first surface, a second surface opposite to the first surface, and a plurality of first pads selectively formed on the first surface side, comprising:
a base plate having a first surface, a second surface opposite to the first surface, and a plurality of first through-holes corresponding respectively to the first pads.

12. The reinforcing plate according to claim 11, wherein the base plate further includes a plurality of second pads to seal the openings, on the second surface side, of the first through-holes and a second through-hole not corresponding to any of the first pads.

13. The reinforcing plate according to claim 12, wherein the base plate further includes a plurality of third pads formed on the first surface and a plurality of wirings formed respectively along the inner surfaces of the first through-holes so as to electrically connect the second pad to the third pad.

14. The reinforcing plate according to claim 11, wherein the base plate is transmissive to at least one of visible light and infrared light.

15. The reinforcing plate according to claim 14, wherein the base plate is made of glass, resin, or silicon.

16. The reinforcing plate according to claim 11, wherein the sidewall of each of the first through-holes inclines as broadened toward the first surface side from the second surface side.

17. The reinforcing plate according to claim 12, wherein the inner surface of the second through-hole inclines as broadened toward the first surface side from the second surface side.

18. The reinforcing plate according to claim 16, wherein an inclination angle of the inner surface is 10 degree or more, and is 20 degree or less.
